(19) United States
(12) Patent Application Publication
(10) Pub. No.: US 2026/0229880 A1
(43) Pub. Date: Aug. 6, 2026

(54) INRUSH CURRENT SUPPRESSION CIRCUIT

(71) Applicant: ANPEC ELECTRONICS CORPORATION, HSINCHU (TW)

(72) Inventors: KUN-YI LIN, Hsinchu City (TW); ZI-PING ZUO, Hsinchu City (TW)

(21) Appl. No.: 19/232,832

(22) Filed: Jun. 9, 2025

(30) Foreign Application Priority Data
Feb. 4, 2025 (TW) 114103925

(51) Int. Cl. H02H 9/00; H03K 3/037; H03K 4/06

(52) U.S. Cl. CPC H02H 9/001; H03K 3/037; H03K 4/06

(57) ABSTRACT

An inrush current suppression circuit includes a switch component, a charging circuit, a switch control circuit and a compensation circuit. A first terminal of the switch component is coupled to an input voltage. A control terminal of the switch component is connected to a control node. The charging circuit outputs a charging current to the control node. The switch control circuit sets a current value of a control current according to an output voltage of a second terminal of the switch component and a ramp voltage, and obtains the control current from the control node. The compensation circuit sets a current value of a compensation current according to a control voltage of the control node and the output voltage, and obtains the compensation current from the ramp voltage or supplies the compensation current to the control node.

### CROSS-REFERENCE TO RELATED PATENT APPLICATION

This application claims the benefit of priority to Taiwan Patent Application No. 114103925, filed on Feb. 4, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an inrush current, and more particularly to an inrush current suppression circuit.

### BACKGROUND OF THE DISCLOSURE

When a switch component is switched in a soft switching manner, a voltage of a control terminal of the switch component is gradually increased to be higher than a threshold voltage of the switch component, such that a second terminal of the switch component supplies an output voltage to a load. However, when a voltage of the control terminal of the switch component is gradually increased, a high voltage difference is generated between a divided voltage of the output voltage of the second terminal of the switch component and a ramp voltage. At this time, an amplifier modulates an operational state of the switch component such that the switch component supplies a larger current for more quickly increasing the output voltage of the second terminal of the switch component to reach the ramp voltage. Under this condition, the output voltage of the second terminal of the switch component rises abruptly rather than smoothly, and inrush waves are generated in an output current of the second terminal of the switch component. As a result, the switch component and the load that is connected to the second terminal of the switch component are damaged.

### SUMMARY OF THE DISCLOSURE

In response to the above-referenced technical inadequacies, the present disclosure provides an inrush current suppression circuit. The inrush current suppression circuit includes a switch component, a charging circuit, a switch control circuit and a compensation circuit. A first terminal of the switch component is coupled to an input voltage. A control terminal of the switch component is connected to a control node. The charging circuit is connected to the control node. The charging circuit is configured to output a charging current to the control node. The switch control circuit is connected to a second terminal and the control terminal of the switch component. The switch control circuit is coupled to a ramp voltage. The switch control circuit is configured to set a current value of a control current according to an output voltage of the second terminal of the switch component and the ramp voltage. The switch control circuit is configured to obtain the control current from the control node. The compensation circuit is connected to the control node and the second terminal of the switch component. The compensation circuit is connected to a ramp node between the switch control circuit and the ramp voltage. The compensation circuit is configured to set a current value of a compensation current, according to a control voltage of the control node and the output voltage of the second terminal of the switch component. The compensation circuit is configured to obtain the compensation current from the ramp node.

In order to solve the above-mentioned problems, yet another one of the technical aspects adopted by the present disclosure is to provide an inrush current suppression circuit. The inrush current suppression circuit includes a switch component. A first terminal of the switch component is coupled to an input voltage. A control terminal of the switch component is connected to a control node. The charging circuit is connected to the control node and configured to output a charging current to the control node. The switch control circuit is connected to a second terminal and the control terminal of the switch component. The switch control circuit is coupled to a ramp voltage. The switch control circuit is configured to set a current value of a control current according to an output voltage of the second terminal of the switch component and the ramp voltage. The switch control circuit is configured to obtain the control current from the control node. The compensation circuit is connected to the control node and the second terminal of the switch component. The compensation circuit is configured to set a current value of a compensation current according to a control voltage of the control node and the output voltage of the second terminal of the switch component. The compensation circuit is configured to output the compensation current to the control node.

As described above, the present disclosure provides the inrush current suppression circuit. In the inrush current suppression circuit of the present disclosure, the compensation current is appropriately obtained or supplied for stably controlling the switch component such that the output voltage of the second terminal of the switch component rises smoothly rather than abruptly, and the inrush waves are not generated in the output current of the second terminal of the switch component. Therefore, the switch component of the inrush current suppression circuit of the present disclosure and the load that is connected to the second terminal of the switch component are prevented from being damaged.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a circuit diagram of an inrush current suppression circuit according to a first embodiment of the present disclosure;

FIG. 2 is a circuit diagram of an inrush current suppression circuit according to a second embodiment of the present disclosure;

FIG. 3 is a circuit diagram of an inrush current suppression circuit according to a third embodiment of the present disclosure;

FIG. 4 is a circuit diagram of a compensation circuit included in an inrush current suppression circuit according to a fourth embodiment of the present disclosure;

FIG. 5 is a flowchart diagram of the inrush current suppression circuit according to the first embodiment to a sixth embodiment of the present disclosure;

FIG. 6 is a waveform diagram of signals of the inrush current suppression circuit according to the first to fourth embodiments of the present disclosure;

FIG. 7 is a waveform diagram of signals of the inrush current suppression circuit of the first to fourth embodiments of the present disclosure and a conventional inrush current suppression circuit;

FIG. 8 is a circuit diagram of the inrush current suppression circuit according to the fifth embodiment of the present disclosure;

FIG. 9 is a circuit diagram of a compensation circuit included in the inrush current suppression circuit according to the sixth embodiment of the present disclosure; and

FIG. 10 is a waveform diagram of signals of the inrush current suppression circuit of the fifth and sixth embodiments of the present disclosure and the conventional inrush current suppression circuit.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

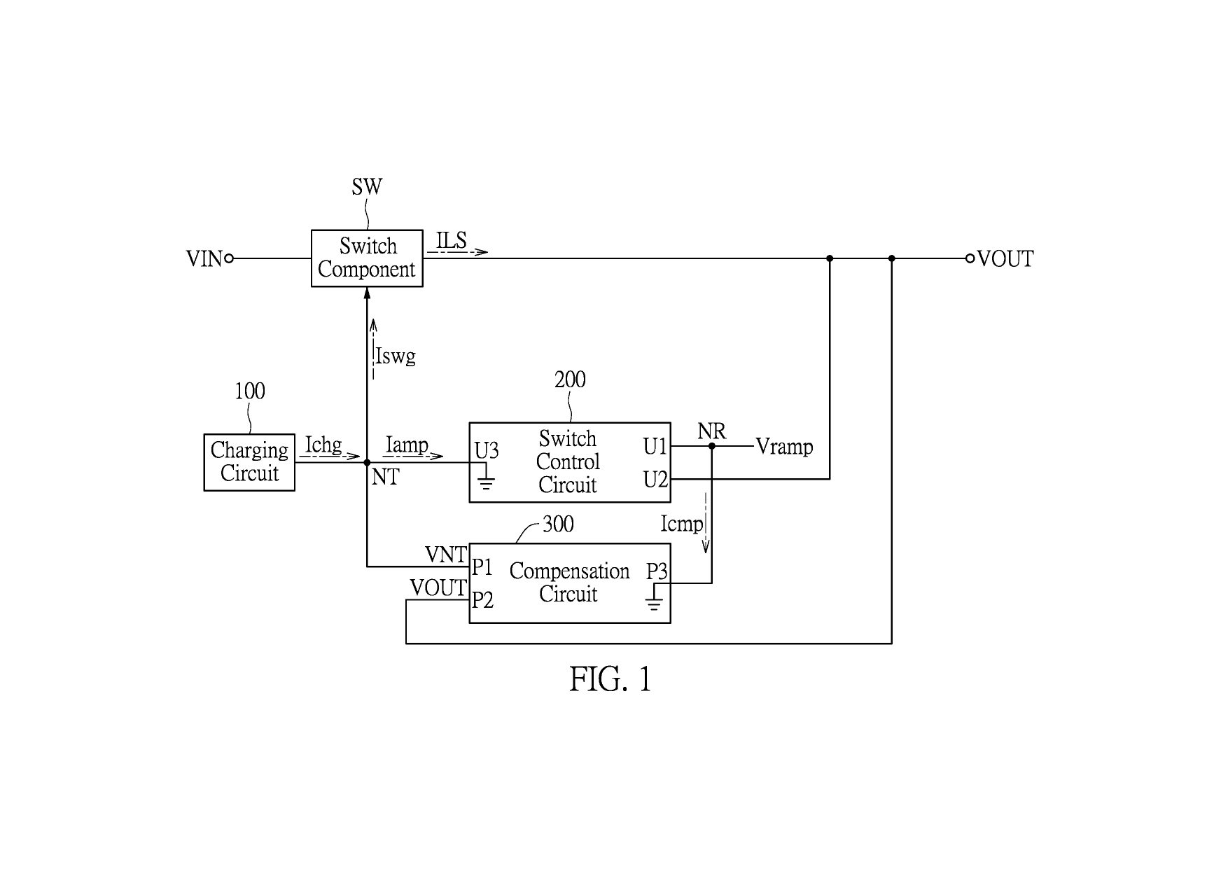

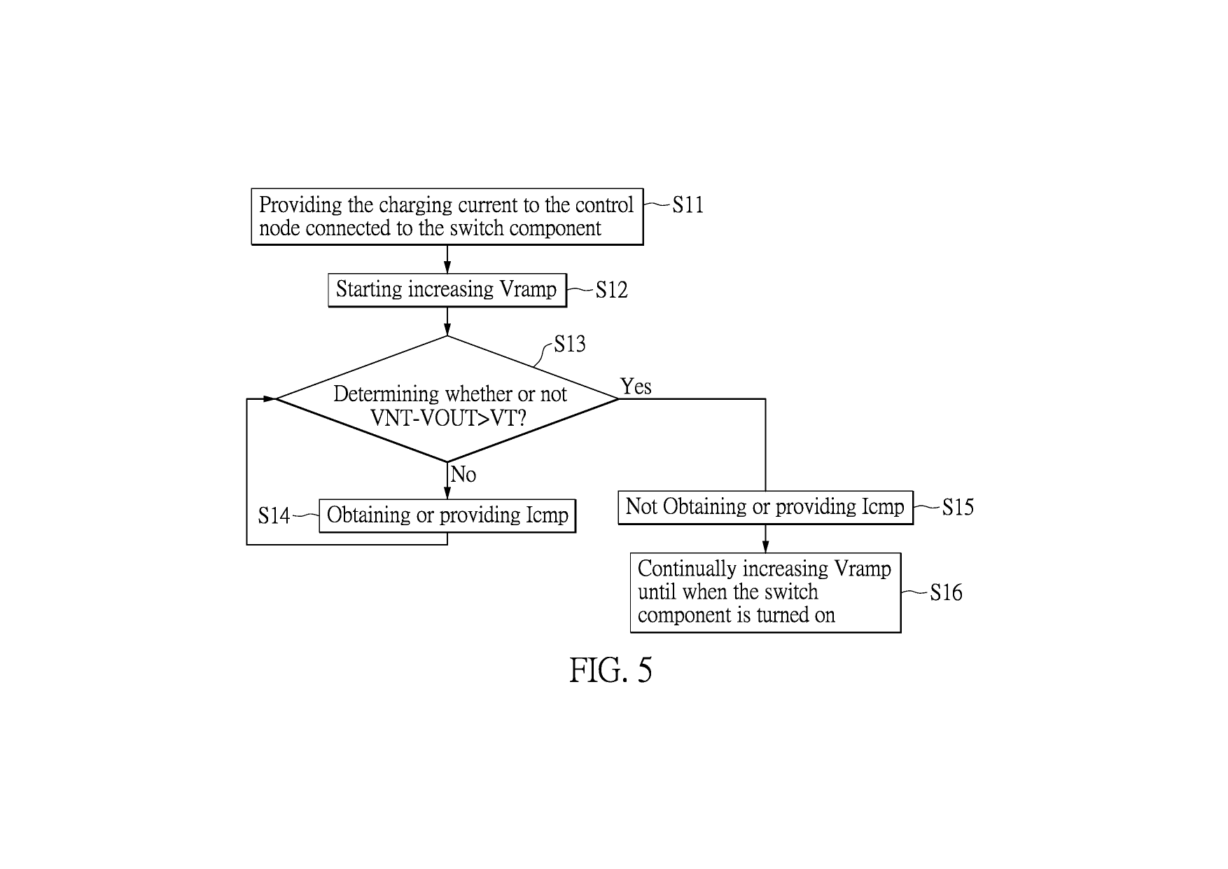

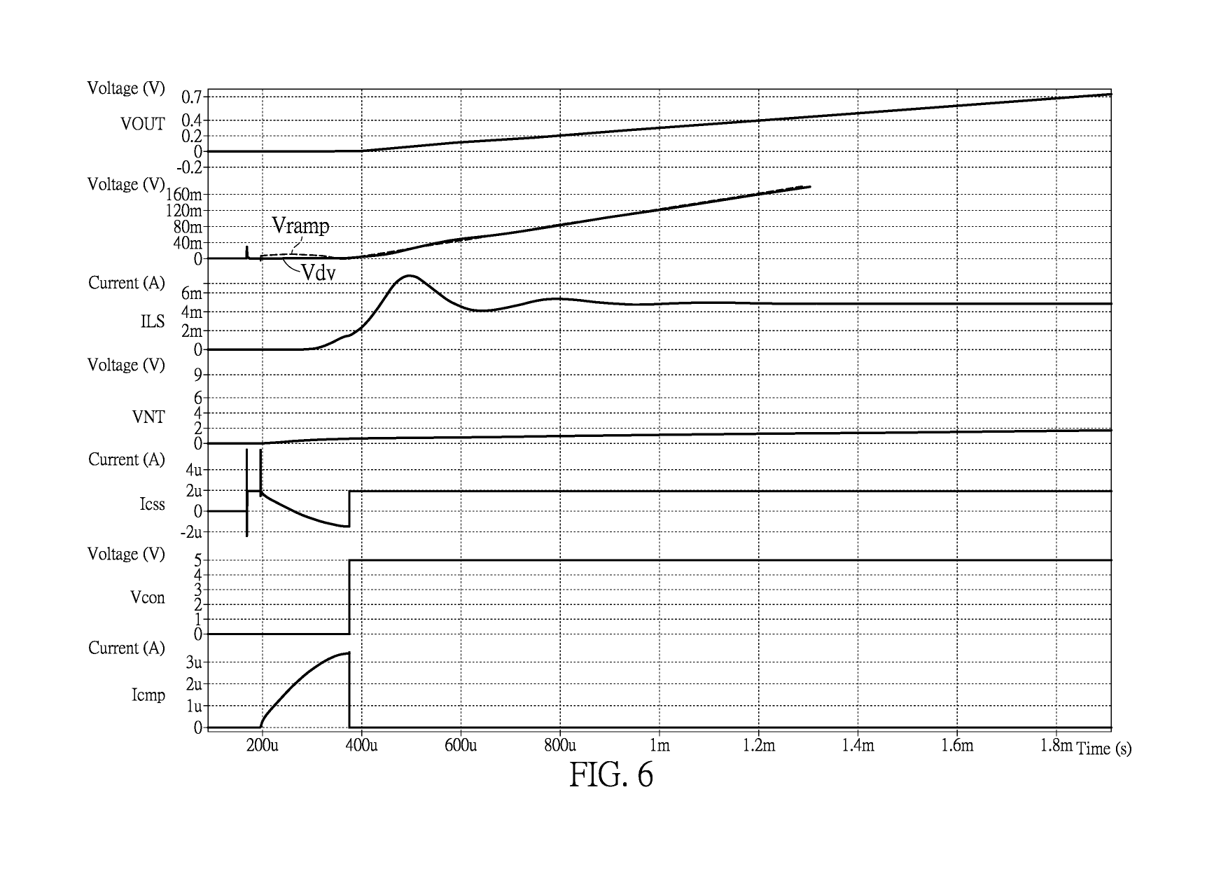

Reference is made to FIGS. 1, 5 and 6, in which FIG. 1 is a circuit diagram of an inrush current suppression circuit according to a first embodiment of the present disclosure, FIG. 5 is a flowchart diagram of the inrush current suppression circuit according to the first embodiment to a sixth embodiment of the present disclosure, and FIG. 6 is a waveform diagram of signals of the inrush current suppression circuit according to the first to fourth embodiments of the present disclosure.

As shown in FIG. 1, in the first embodiment, the inrush current suppression circuit of the present disclosure includes a switch component SW, a charging circuit 100, a switch control circuit 200 and a compensation circuit 300.

A first terminal (such as a drain terminal) of the switch component SW is coupled to an input voltage VIN. A second terminal (such as a source terminal) of the switch component SW is used as an output terminal of the inrush current suppression circuit of the present disclosure, and may be connected to a load. A voltage of the second terminal of the switch component SW is used as an output voltage VOUT. A control terminal (such as a gate terminal) of the switch component SW and the charging circuit 100 are connected to a control node NT.

A first terminal U1 (such as an inverting input terminal) of the switch control circuit 200 is coupled to a ramp voltage Vramp. A second terminal U2 (such as a non-inverting input terminal) of the switch control circuit 200 is connected to the second terminal of the switch component SW. A third terminal U3 of the switch control circuit 200 is connected to the control node NT.

The charging circuit 100 outputs a charging current Ichg to the control node NT (in process S11 of FIG. 5) such that the control terminal of the switch component SW receives a control current Iswg from the control node NT. At this time, the control current Iswg received by the control terminal of the switch component SW is all or parts of the charging current Ichg outputted by the charging circuit 100.

When the control current Iswg received by the control terminal of the switch component SW is increased, a voltage of the control terminal of the switch component SW is increased. As a result, an output current ILS flowing through the second terminal of the switch component SW is increased such that the output voltage VOUT of the second terminal of the switch component SW is increased.

The switch control circuit 200 obtains the output voltage VOUT of the second terminal of the switch component SW. The switch control circuit 200, according to the output voltage VOUT of the second terminal of the switch component SW and the ramp voltage Vramp, determines whether to obtain a control current Iamp from the control node NT to which the control terminal of the switch component SW, the charging circuit 100 and the third terminal U3 of the switch control circuit 200 are connected, and sets an amount of the control current Iamp being obtained from the control node NT.

For example, the switch control circuit 200 includes an amplifier. The amplifier is configured to amplify a voltage difference between the output voltage VOUT of the second terminal of the switch component SW and the ramp voltage Vramp by a gain to generate an amplified voltage difference. The amplifier, according to the amplified voltage difference, sets the amount of the control current Iamp that is obtained from (or supplied to) the control node NT.

It is worth noting that, when the switch component SW is switched in a soft switching manner, the voltage of the control terminal of the switch component SW is increased slowly. A long period of time is required for increasing the voltage of the control terminal of the switch component SW to reach a threshold voltage of the switch component SW such that the switch component SW is turned on. Therefore, a voltage difference between an initial voltage value of the output voltage VOUT of the second terminal of the switch component SW and the ramp voltage Vramp is too high. Under this condition, the control terminal of the switch component SW receives the control current Iswg having a large current value from the control node NT. As a result, the switch component SW is quickly turned on for outputting the output voltage VOUT having a voltage value required for the load from the second terminal of the switch component SW to the load. At this time, the output voltage VOUT of the second terminal of the switch component SW rises abruptly rather than smoothly. The control terminal of the switch component SW even receives the control current Iswg having inrush waves, and the output current ILS of the second terminal of the switch component SW has inrush waves. As a result, the switch component SW and the load that is connected to the second terminal of the switch component SW are damaged.

In order to prevent the switch component SW and the load connected thereto from being damaged, the inrush current suppression circuit of the present disclosure not only includes the switch component SW, the charging circuit 100 and the switch control circuit 200, but further includes the compensation circuit 300.

A first terminal P1 of the compensation circuit 300 is connected to the control node NT. A second terminal P2 of the compensation circuit 300 is connected to the second terminal of the switch component SW. A third terminal P3 of the compensation circuit 300 is connected to a ramp node NR between the first terminal U1 of the switch control circuit 200 and the ramp voltage Vramp.

The compensation circuit 300, according to a control voltage VNT of the control node NT and the output voltage VOUT of the second terminal of the switch component SW, determines whether to obtain a compensation current Icmp from the ramp node NR between the first terminal U1 of the switch control circuit 200 and the ramp voltage Vramp, and sets an amount of the compensation current Icmp being obtained from the ramp node NR.

For example, the compensation circuit 300 subtracts the output voltage VOUT of the second terminal of the switch component SW from the control voltage VNT to obtain a voltage difference. When the compensation circuit 300 determines that the voltage difference, that is the control voltage VNT from which the output voltage VOUT is subtracted, is not higher than a threshold voltage VT of the switch component SW, the compensation circuit 300 starts performing a protection process (in process S13 in FIG. 5). In the protection process, the compensation circuit 300 obtains the compensation current Icmp from the ramp node NR between the first terminal U1 of the switch control circuit 200 and the ramp voltage Vramp (in process S14 in FIG. 5) for reducing the ramp voltage Vramp of the ramp node NR. As a result, a voltage difference between the ramp voltage Vramp and the output voltage VOUT of the second terminal of the switch component SW is reduced. As shown in FIG. 6, the ramp voltage Vramp is reduced to be appropriately equal to the output voltage VOUT of the second terminal of the switch component SW.

Further, when the ramp voltage Vramp is reduced to be appropriately equal to the output voltage VOUT of the second terminal of the switch component SW, the switch control circuit 200 increases the amount of the control current Iamp being obtained from the control node NT earlier, so as to reduce the voltage of the control terminal of the switch component SW. As a result, inrush waves are prevented from being generated in the output current ILS and the output voltage VOUT of the second terminal of the switch component SW. Therefore, the switch component SW and the load that is connected to the second terminal of the switch component SW are effectively prevented from being damaged.

When the compensation circuit 300 determines that the voltage difference, that is the control voltage VNT from which the output voltage VOUT is subtracted, is higher than the threshold voltage VT of the switch component SW (in process S13 in FIG. 5), the compensation circuit 300 stops performing the protection process. That is, the compensation circuit 300 stops obtaining the compensation current Icmp from the ramp node NR between the first terminal U1 of the switch control circuit 200 and the ramp voltage Vramp (in process S15 in FIG. 5).

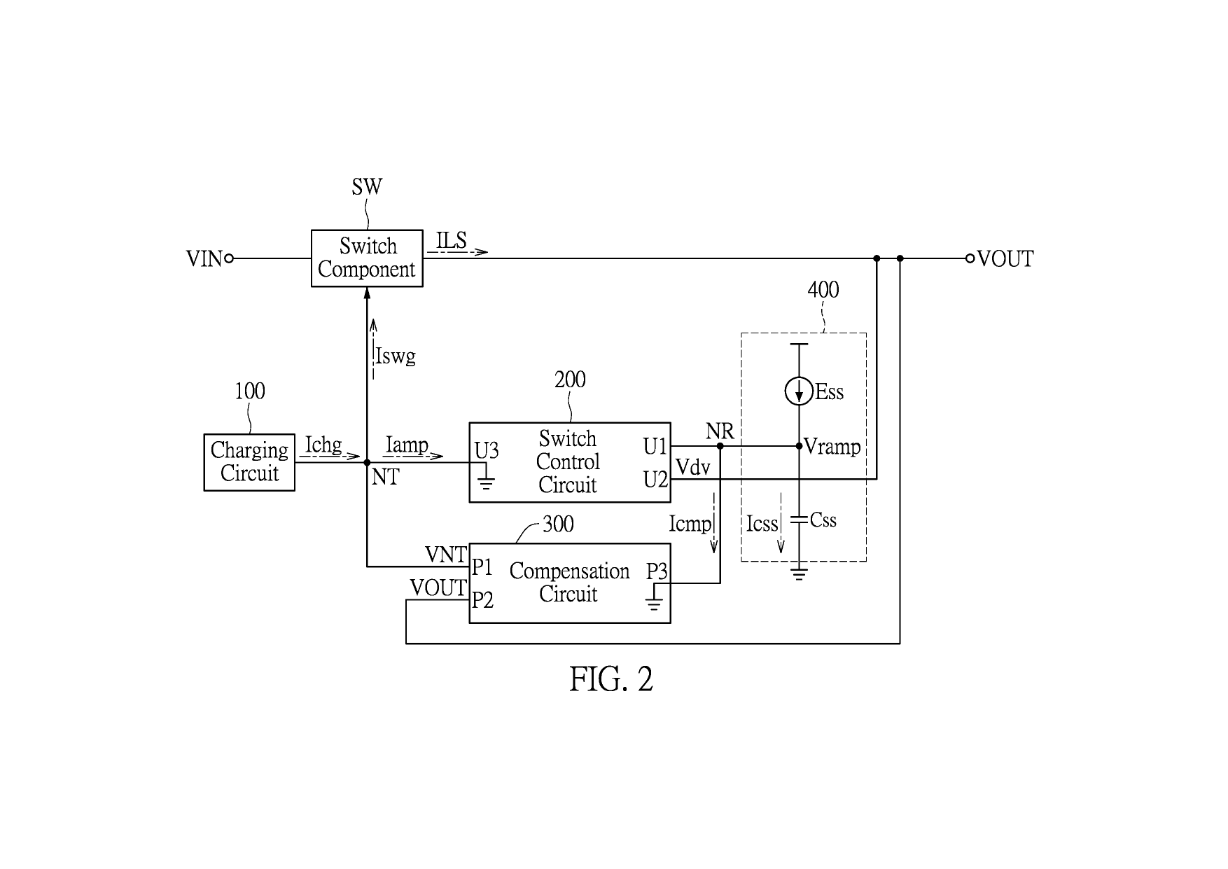

Reference is made to FIGS. 2 and 5, in which FIG. 2 is a circuit diagram of an inrush current suppression circuit according to a second embodiment of the present disclosure, and FIG. 5 is a flowchart diagram of the inrush current suppression circuit according to the first to sixth embodiments of the present disclosure.

The descriptions of the second embodiment of the present disclosure that are the same as the descriptions of the first embodiment of the present disclosure are not repeated herein. A difference between the second and first embodiments of the present disclosure is that, as shown in FIG. 2, in the second embodiment, the inrush current suppression circuit of the present disclosure not only includes the switch component SW, the charging circuit 100, the switch control circuit 200 and the compensation circuit 300, but also includes a ramp voltage generating circuit 400.

The ramp voltage generating circuit 400 is connected to the first terminal U1 of the switch control circuit 200 through the ramp node NR. The ramp voltage generating circuit 400 outputs the ramp voltage Vramp to the ramp node NR, and then the first terminal U1 of the switch control circuit 200 obtains the ramp voltage Vramp from the ramp node NR.

For example, as shown in FIG. 2, the ramp voltage generating circuit 400 includes a ramp capacitor Css and a ramp current source Ess. A first terminal of the ramp capacitor Css is connected to the ramp current source Ess and the first terminal U1 of the switch control circuit 200. A second terminal of the ramp capacitor Css is grounded.

The ramp current source Ess outputs a ramp current to the ramp capacitor Css for charging the ramp capacitor Css. As a result, the ramp voltage Vramp of the first terminal of the ramp capacitor Css is gradually increased to a target ramp voltage value (in process S12 of FIG. 5). A voltage of the first terminal of the ramp capacitor Css is used as the ramp voltage Vramp and is inputted to the first terminal U1 of the switch control circuit 200.

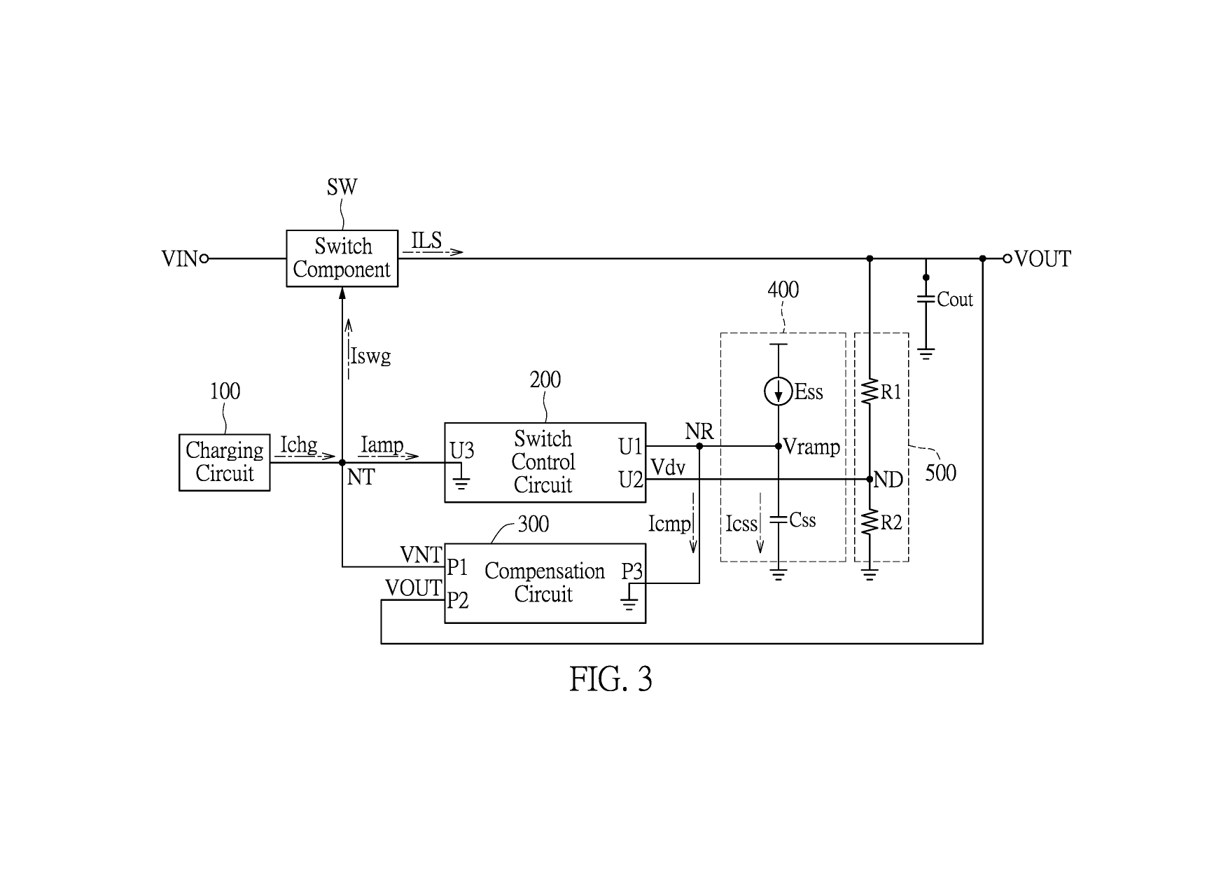

Reference is made to FIG. 3, which is a circuit diagram of an inrush current suppression circuit according to a third embodiment of the present disclosure.

The descriptions of the third embodiment of the present disclosure that are the same as the descriptions of the first and second embodiments of the present disclosure are not repeated herein. A difference between the third and second embodiments of the present disclosure is that, the inrush current suppression circuit of the third embodiment of the present disclosure not only includes the switch component SW, the charging circuit 100, the switch control circuit 200, the compensation circuit 300 and the ramp voltage generating circuit 400, but also includes a voltage dividing circuit 500 and an output capacitor Cout.

A first terminal of the output capacitor Cout is connected to the second terminal of the switch component SW. A second terminal of the output capacitor Cout is grounded.

The load may be connected to the first terminal of the output capacitor Cout or the second terminal of the switch component SW.

The voltage dividing circuit 500 is connected to the second terminal of the switch component SW or the first terminal of the output capacitor Cout, and is connected to the second terminal U2 of the switch control circuit 200.

As shown in FIG. 3, in the third embodiment, the voltage dividing circuit 500 divides the output voltage VOUT to output a divided voltage of the output voltage VOUT as a feedback voltage Vdv. In contrast, as shown in FIG. 2, in the second embodiment, the feedback voltage Vdv is the output voltage VOUT. In practice, the feedback voltage Vdv that is the divided voltage of the output voltage VOUT in FIG. 3 may be replaced with the output voltage VOUT.

The switch control circuit 200, according to the control voltage VNT of the control node NT and the feedback voltage Vdv, a voltage difference between the feedback voltage Vdv and the control voltage VNT or the amplified voltage difference that is the voltage difference multiplied by a gain, determines whether to obtain the compensation current Icmp from the ramp node NR between the first terminal U1 of the switch control circuit 200 and the ramp voltage Vramp, and sets the amount of the compensation current Icmp.

For example, the voltage dividing circuit 500 includes a first voltage dividing resistor R1 and a second voltage dividing resistor R2. A first terminal of the first voltage dividing resistor R1 is connected to the second terminal of the switch component SW or the first terminal of the output capacitor Cout. A first terminal of the second voltage dividing resistor R2 (that is used as an input terminal of the voltage dividing circuit 500) is connected to a second terminal of the first voltage dividing resistor R1. A voltage dividing node ND between the first terminal of the second voltage dividing resistor R2 and the second terminal of the first voltage dividing resistor R1 (that is used as an output terminal of the voltage dividing circuit 500) is connected to the second terminal U2 of the switch control circuit 200. A voltage of the voltage dividing node ND between the first terminal of the second voltage dividing resistor R2 and the second terminal of the first voltage dividing resistor R1 is the divided voltage of the output voltage VOUT. The divided voltage of the output voltage VOUT is used as the feedback voltage Vdv and is inputted to the second terminal U2 of the switch control circuit 200.

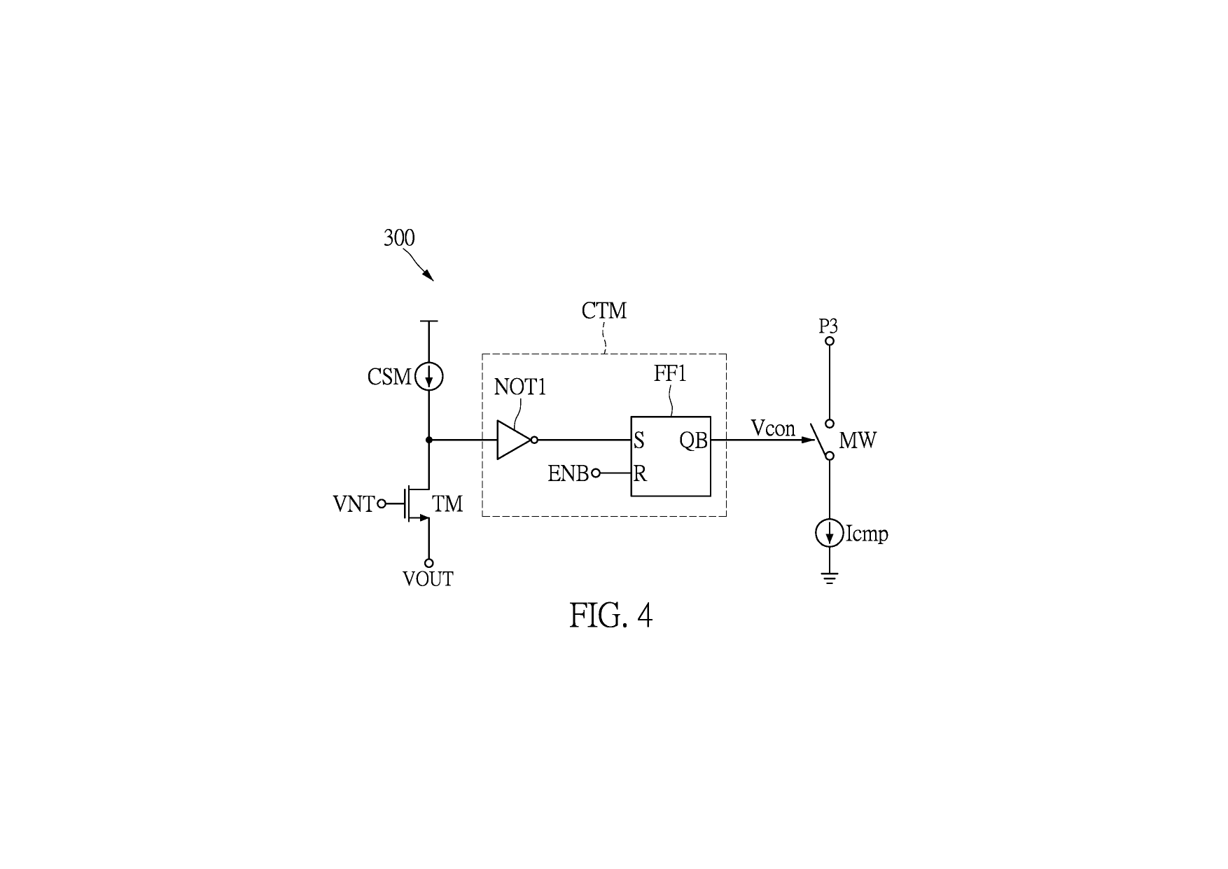

Reference is made to FIGS. 4 to 6, in which FIG. 4 is a circuit diagram of a compensation circuit included in an inrush current suppression circuit according to a fourth embodiment of the present disclosure, FIG. 5 is a flowchart diagram of the inrush current suppression circuit according to the first to sixth embodiments of the present disclosure, and FIG. 6 is a waveform diagram of signals of the inrush current suppression circuit according to the first to fourth embodiments of the present disclosure.

The compensation circuit 300 as shown in FIGS. 1 to 3 may be the same as the compensation circuit 300 shown in FIG. 4. As shown in FIG. 4, the compensation circuit 300 includes a compensation transistor TM, a bias current source CSM, a compensation control circuit CTM and a compensation switch MW.

A first terminal of the compensation transistor TM is connected to the bias current source CSM. The bias current source CSM supplies a bias current Ibias to the first terminal of the compensation transistor TM.

A second terminal of the compensation transistor TM is connected to the second terminal of the switch component SW or the first terminal of the output capacitor Cout, and receives the output voltage VOUT from the second terminal of the switch component SW or the first terminal of the output capacitor Cout.

A control terminal of the compensation transistor TM is connected to the control node NT to which the control terminal of the switch component SW, the charging circuit 100 and the third terminal U3 of the switch control circuit 200 are connected. The control terminal of the compensation transistor TM receives the control voltage VNT from the control node NT.

The bias current source CSM outputs a compensation control voltage Vcon according to a voltage of the first terminal of the compensation transistor TM.

For example, the compensation control circuit CTM may include an inverter NOT1 and a flip-flop FF1 as shown in FIG. 4, or in practice, includes other logic circuit components. As shown in FIG. 4, an input terminal of the inverter NOT1 (that is used as an input terminal of the compensation control circuit CTM) is connected to the first terminal of the compensation transistor TM.

For example, the flip-flop FF1 is a SR flip-flop as shown in FIG. 4, or in practice, is another type of flip-flop or other logic circuit. A first input terminal S of the flip-flop FF1 is connected to an output terminal of the inverter NOT1. A second input terminal R of the flip-flop FF1 is coupled to an enable logic level ENB. An inverting output terminal QB of the flip-flop FF1 is connected to a control terminal of the compensation switch MW.

A first terminal of the compensation switch MW shown in FIG. 4 is used as the third terminal P3 of the compensation circuit 300, and is connected to the ramp node NR between the first terminal U1 of the switch control circuit 200 and the ramp voltage Vramp (or the ramp voltage generating circuit 400) as shown in FIGS. 1 to 3. A second terminal of the compensation switch MW is grounded. The control terminal of the compensation switch MW receives the compensation control voltage Vcon from the inverting output terminal QB of the flip-flop FF1 (that is used as an output terminal of the compensation control circuit CTM).

As shown in FIG. 6, when the output voltage VOUT of the second terminal of the switch component SW or the first terminal of the output capacitor Cout is still a zero value or a low voltage value, a high voltage difference is generated between the feedback voltage Vdv (that is the divided voltage) of the output voltage VOUT and the ramp voltage Vramp.

When the voltage difference that is obtained by subtracting the output voltage VOUT received by the second terminal of the compensation transistor TM from the control voltage VNT received by the control terminal of the compensation transistor TM is not higher than the threshold voltage VT of the compensation transistor TM (in process S13 of FIG. 5), the control terminal of the compensation switch MW receives the compensation control voltage Vcon at a high level from the inverting output terminal QB of the flip-flop FF1. At this time, the inrush current suppression circuit of the present disclosure performs the protection process. In the protection process, the compensation circuit 300 obtains the compensation current Icmp from the ramp node NR between the first terminal U1 of the switch control circuit 200 and the ramp voltage Vramp (or the ramp voltage generating circuit 400) (in process S14 of FIG. 5). In other words, the compensation current Icmp flows from the ramp node NR between the first terminal U1 of the switch control circuit 200 and the ramp voltage Vramp (or the ramp voltage generating circuit 400) through the compensation circuit 300 to ground, such that the ramp voltage Vramp of the ramp node NR is reduced. As shown in FIG. 6, after the inverting output terminal QB of the flip-flop FF1 outputs the compensation control voltage Vcon at the high level, the ramp voltage Vramp is reduced such that the voltage difference between the output voltage VOUT of the second terminal of the switch component SW and the ramp voltage Vramp is reduced.

For example, a current value of the compensation current Icmp is equal to a preset value multiplied by the voltage difference that is obtained by subtracting the output voltage VOUT received by the second terminal of the compensation transistor TM from the control voltage VNT received by the control terminal of the compensation transistor TM.

When the voltage difference that is obtained by subtracting the output voltage VOUT received by the second terminal of the compensation transistor TM from the control voltage VNT received by the control terminal of the compensation transistor TM is higher than the threshold voltage VT of the compensation transistor TM, the compensation transistor TM is turned off. At this time, the inrush current suppression circuit of the present disclosure stops performing the protection process. That is, the compensation circuit 300 stops obtaining the compensation current Icmp from the ramp node NR between the first terminal U1 of the switch control circuit 200 and the ramp voltage Vramp (or the ramp voltage generating circuit 400).

Further, when the compensation circuit 300 stops obtaining the compensation current Icmp from the ramp node NR, the ramp voltage Vramp of the ramp node NR stops being reduced. At the same time, the ramp current source Ess continually supplies a ramp current Icss to the ramp capacitor Css such that the ramp voltage Vramp of the ramp capacitor Css is continually increased (in process S16 of FIG. 5).

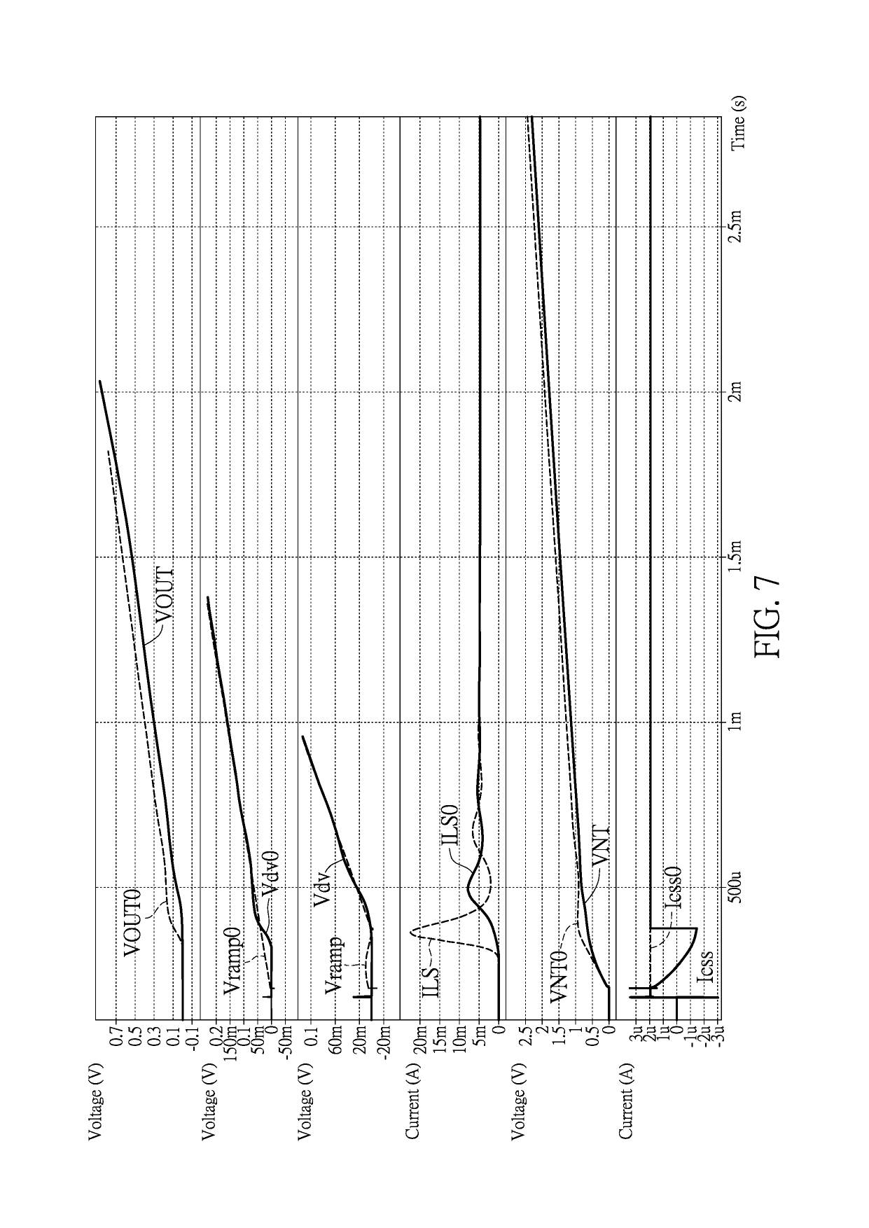

Reference is made to FIGS. 1 to 7, in which FIG. 7 is a waveform diagram of signals of the inrush current suppression circuit of the first to fourth embodiments of the present disclosure and a conventional inrush current suppression circuit.

As shown in FIG. 7, in comparison with the conventional inrush current suppression circuit having an output voltage VOUT0 rising abruptly, the output voltage VOUT of the inrush current suppression circuit of the present disclosure shown in FIGS. 1 to 4 rises smoothly.

In the conventional inrush current suppression circuit, a feedback voltage Vdv0 of the output voltage VOUT0 is slowly increased to reach a ramp voltage Vramp0 for a long period of time. In contrast, in the inrush current suppression circuit of the present disclosure, the ramp voltage Vramp of the inrush current suppression circuit is pulled down such that the output voltage VOUT more quickly reaches the ramp voltage Vramp.

In comparison with a ramp current Icss0 of the conventional inrush current suppression circuit, the compensation current Icmp is obtained from the ramp node NR by the inrush current suppression circuit of the present disclosure such that the ramp current Icss that is received from the ramp current source Ess by the ramp capacitor Css is reduced. As a result, the ramp voltage Vramp of the ramp node NR of the inrush current suppression circuit of the present disclosure is pulled down.

A high voltage difference is generated between the ramp voltage Vramp0 and the feedback voltage Vdv0 of the output voltage VOUT0 of the conventional inrush current suppression circuit. Under this condition, in the conventional inrush current suppression circuit, a control voltage VNT0 having a high voltage is supplied to a control terminal of a switch component for more quickly increasing the feedback voltage Vdv0 of the output voltage VOUT0 to reach the ramp voltage Vramp0. As a result, in the conventional inrush current suppression circuit, an inrush wave is generated in an output current ILS0 of a second terminal of the switch component. That is, the output current ILS0 momentarily reaches a large current value. The switch component of the conventional inrush current suppression circuit and the load connected thereto are damaged by the output current ILS0.

In contrast, in the inrush current suppression circuit of the present disclosure, the ramp voltage Vramp is pulled down such that only a low voltage difference is generated between the output voltage VOUT and the ramp voltage Vramp. Under this condition, an inrush wave is not generated in the output current ILS of the switch component SW of the inrush current suppression circuit of the present disclosure. Therefore, the inrush current suppression circuit of the present disclosure and the load connected thereto are not damaged, and can operate normally.

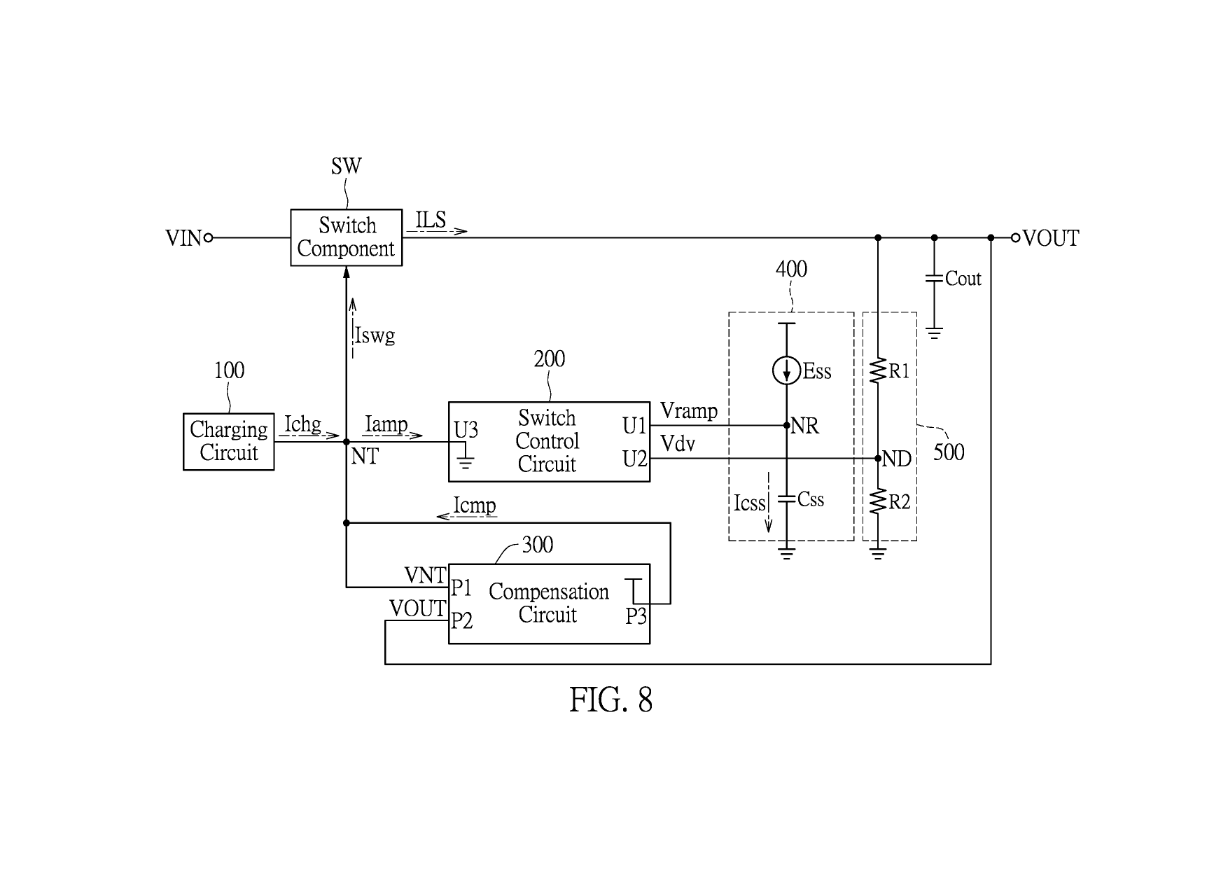

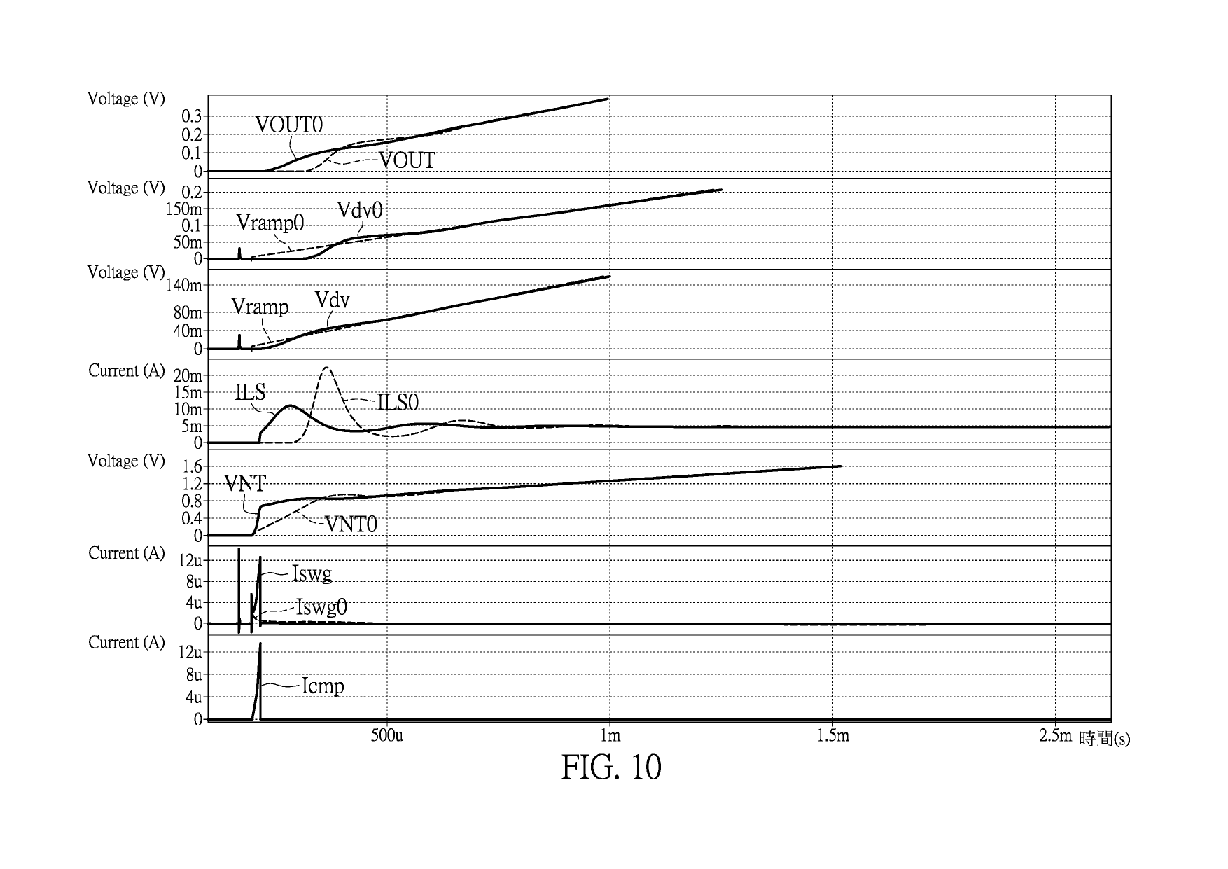

Reference is made to FIGS. 8 and 10, in which FIG. 8 is a circuit diagram of the inrush current suppression circuit according to the fifth embodiment of the present disclosure, and FIG. 10 is a waveform diagram of signals of the inrush current suppression circuit of the fifth and sixth embodiments of the present disclosure and the conventional inrush current suppression circuit.

The descriptions of the fifth embodiment of the present disclosure that are the same as the descriptions of the first to third embodiment of the present disclosure are not repeated herein. Differences between the fifth and third embodiments of the present disclosure are described as follows.

As shown in FIG. 3, in the third embodiment, the third terminal U3 of the compensation circuit 300 is connected to the ramp node NR between the first terminal U1 of the switch control circuit 200 and the ramp voltage Vramp (or the ramp voltage generating circuit 400), and obtains the compensation current Icmp from the ramp node NR.

In contrast, as shown in FIG. 8, in the fifth embodiment, the third terminal U3 of the compensation circuit 300 is connected to the control node NT to which the control terminal of the switch component SW, the charging circuit 100 and the third terminal U3 of the switch control circuit 200 are connected. The compensation circuit 300, according to the control voltage VNT of the control node NT and the output voltage VOUT of the second terminal of the switch component SW or the first terminal of the output capacitor Cout, determines whether to supply the compensation current Icmp, and sets the current value of the compensation current Icmp. When the compensation circuit 300 determines to supply the compensation current Icmp, the compensation circuit 300 outputs the compensation current Icmp to the control node NT as shown in FIGS. 8 and 10.

Therefore, the control voltage VNT and the control current Iswg that is obtained from the control node NT by the control terminal of the switch component SW of the inrush current suppression circuit of the fifth embodiment of the present disclosure are respectively larger than a control voltage VNT0 and a control current Iswg0 that is obtained by the control terminal of the switch component of the conventional inrush current suppression circuit. As a result, in the fifth embodiment of the present disclosure, the feedback voltage Vdv of the output voltage VOUT of the second terminal of the switch component SW is pulled up to the ramp voltage Vramp earlier. Therefore, in the fifth embodiment of the present disclosure, the switch control circuit 200 earlier obtains the control current Iamp from the control node NT, thereby preventing the inrush wave from being generated in the output current ILS of the second terminal of the switch component SW.

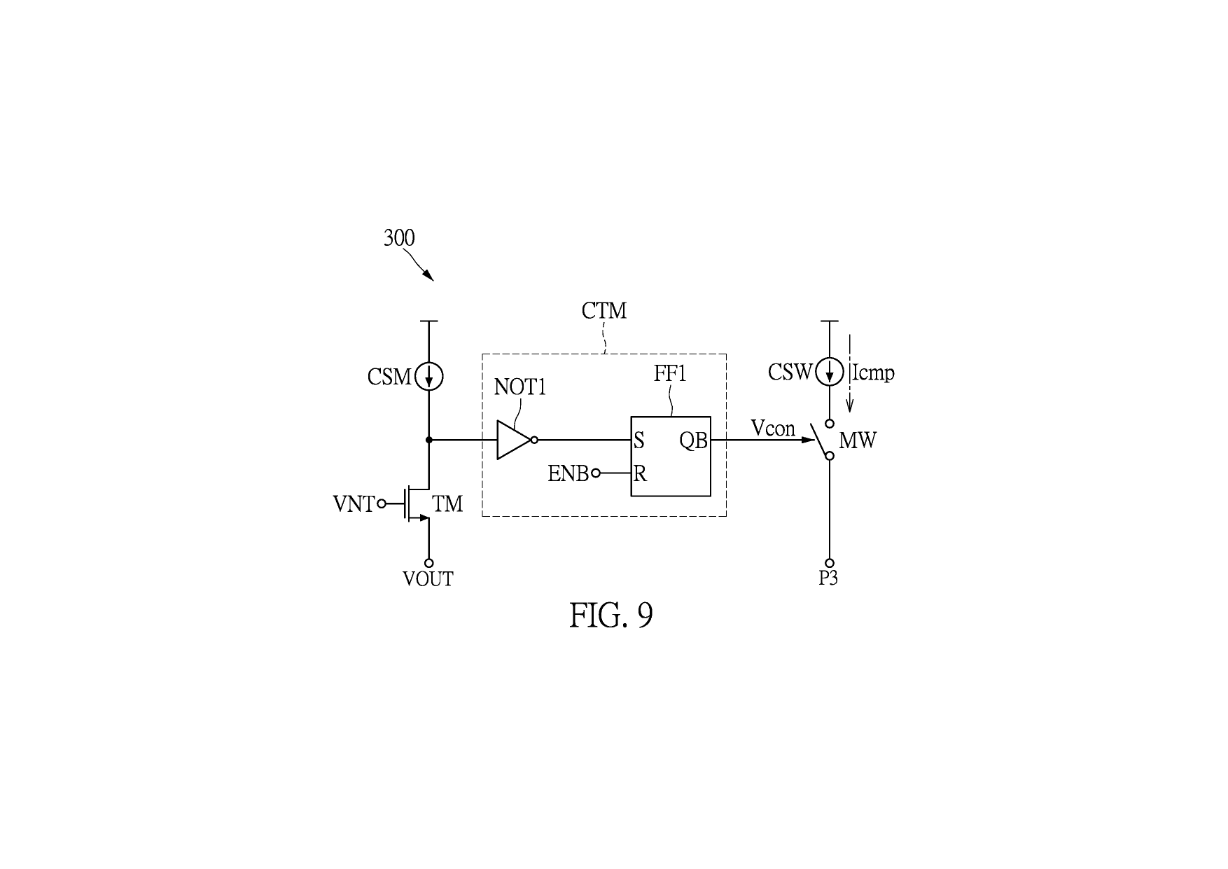

Reference is made to FIG. 9, which is a circuit diagram of a compensation circuit included in the inrush current suppression circuit according to the sixth embodiment of the present disclosure.

A configuration of the inrush current suppression circuit of the sixth embodiment of the present disclosure is substantially the same as that of the fourth embodiment of the present disclosure. The descriptions of the sixth embodiment that are the same as the descriptions of the fourth embodiment are not repeated herein. Differences between the sixth and fourth embodiments are described as follows.

In the fourth embodiment, the first terminal of the compensation switch MW of the compensation circuit 300 of the fourth embodiment of the present disclosure as shown in FIG. 4 is used as the third terminal P3 of the compensation circuit 300 as shown in FIG. 3, and is connected to the ramp node NR between the first terminal U1 of the switch control circuit 200 and the ramp voltage Vramp (or the ramp voltage generating circuit 400) as shown in FIG. 3. The second terminal of the compensation switch MW is grounded. One part of a current supplied by the ramp current source Ess shown in FIG. 3 as the compensation current Icmp flows from the ramp node NR into the compensation circuit 300, and then flows through the compensation switch MW inside the compensation circuit 300 to ground as shown in FIG. 4. As shown in FIG. 3, another part of the current supplied by the ramp current source Ess as the ramp current Icss flows to the ramp capacitor Css. As a result, a voltage of the ramp capacitor Css is reduced such that the ramp voltage Vramp of the ramp node NR is reduced.

In contrast, as shown in FIG. 9, in the sixth embodiment, the compensation circuit 300 of the present disclosure further includes a compensation current source CSW. The compensation current source CSW is connected to the first terminal of the compensation switch MW. The second terminal of the compensation switch MW shown in FIG. 9 is used as the third terminal P3 of the compensation circuit 300, and is connected to the control node NT shown in FIG. 8. The compensation current Icmp supplied by the compensation current source CSW shown in FIG. 9 flows through the compensation switch MW to the control node NT shown in FIG. 8, such that the control current Iswg that is obtained from the control node NT by the control terminal of the switch component SW shown in FIG. 8 is increased. As a result, the feedback voltage Vdv of the output voltage VOUT of the second terminal of the switch component SW is pulled up to reach the ramp voltage Vramp earlier, such that the switch control circuit 200 earlier obtains the control current Iamp from the control node NT, thereby preventing the inrush wave from being generated in the output current ILS of the second terminal of the switch control circuit 200.

In conclusion, the present disclosure provides the inrush current suppression circuit. In the inrush current suppression circuit of the present disclosure, the compensation current is appropriately obtained or supplied for stably controlling the switch component such that the output voltage of the second terminal of the switch component rises smoothly rather than abruptly, and the inrush wave is not generated in the output current of the second terminal of the switch component. Therefore, the switch component of the inrush current suppression circuit of the present disclosure and the load that is connected to the second terminal of the switch component are prevented from being damaged.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An inrush current suppression circuit, comprising:
a switch component, wherein a first terminal of the switch component is coupled to an input voltage, and a control terminal of the switch component is connected to a control node;
a charging circuit connected to the control node and configured to output a charging current to the control node;
a switch control circuit, wherein the switch control circuit is connected to a second terminal and the control terminal of the switch component and coupled to a ramp voltage, configured to set a current value of a control current according to an output voltage of the second terminal of the switch component and the ramp voltage, and configured to obtain the control current from the control node; and
a compensation circuit, wherein the compensation circuit is connected to the control node and the second terminal of the switch component, connected to a ramp node between the switch control circuit and the ramp voltage, configured to set a current value of a compensation current according to a control voltage of the control node and the output voltage of the second terminal of the switch component, and configured to obtain the compensation current from the ramp node.

2. The inrush current suppression circuit according to claim 1, further comprising:
a voltage dividing circuit connected to the second terminal of the switch component and the switch control circuit, and configured to divide the output voltage to output a divided voltage;
wherein the switch control circuit is configured to set a current value of the control current according to the control voltage and the divided voltage.

3. The inrush current suppression circuit according to claim 2, wherein the voltage dividing circuit includes:
a first voltage dividing resistor, wherein a first terminal of the first voltage dividing resistor is connected to the second terminal of the switch component; and
a second voltage dividing resistor, wherein a first terminal of the second voltage dividing resistor is connected to a second terminal of the first voltage dividing resistor, and a voltage dividing node between the first terminal of the second voltage dividing resistor and the second terminal of the first voltage dividing resistor is connected to the switch control circuit.

4. The inrush current suppression circuit according to claim 1, further comprising:
a ramp voltage generating circuit connected to the switch control circuit, and configured to output the ramp voltage to the switch control circuit.

5. The inrush current suppression circuit according to claim 4, wherein the ramp voltage generating circuit includes:
a ramp capacitor, wherein a first terminal of the ramp capacitor is connected to the switch control circuit, and a second terminal of the ramp capacitor is grounded; and
a ramp current source connected to the first terminal of the ramp capacitor and configured to output a ramp current to the ramp capacitor;
wherein the switch control circuit is configured to receive a voltage of the first terminal of the ramp capacitor as the ramp voltage.

6. The inrush current suppression circuit according to claim 1, further comprising:
an output capacitor, wherein a first terminal of the output capacitor is connected to the second terminal of the switch component, and a second terminal of the output capacitor is grounded.

7. The inrush current suppression circuit according to claim 1, wherein the compensation circuit includes:
a bias current source configured to output a bias current;
a compensation transistor, wherein a first terminal of the compensation transistor is connected to the bias current source, a control terminal of the compensation transistor is connected to the control node, and a second terminal of the compensation transistor is connected to the second terminal of the switch component;
a compensation control circuit, wherein the compensation control circuit is connected to the first terminal of the compensation transistor, and configured to output a compensation control voltage according to a voltage of the first terminal of the compensation transistor; and
a compensation switch, wherein a first terminal of the compensation switch is connected to the ramp node, a second terminal of the compensation switch is grounded, and a control terminal of the compensation switch is connected to the compensation control circuit.

8. The inrush current suppression circuit according to claim 7, wherein the compensation control circuit includes:
an inverter, wherein an input terminal of the inverter is connected to the first terminal of the compensation transistor; and
a flip-flop, wherein a first input terminal of the flip-flop is connected to an output terminal of the inverter, a second input terminal of the flip-flop is coupled to an enable logic level, and an inverting output terminal of the flip-flop is connected to the control terminal of the compensation switch.

9. An inrush current suppression circuit, comprising:
a switch component, wherein a first terminal of the switch component is coupled to an input voltage, and a control terminal of the switch component is connected to a control node;
a charging circuit connected to the control node and configured to output a charging current to the control node;
a switch control circuit, wherein the switch control circuit is connected to a second terminal and the control terminal of the switch component and coupled to a ramp voltage, configured to set a current value of a control current according to an output voltage of the second terminal of the switch component and the ramp voltage, and configured to obtain the control current from the control node; and
a compensation circuit, wherein the compensation circuit is connected to the control node and the second terminal of the switch component, configured to set a current value of a compensation current according to a control voltage of the control node and the output voltage of the second terminal of the switch component, and configured to output the compensation current to the control node.

10. The inrush current suppression circuit according to claim 9, further comprising:
a voltage dividing circuit connected to the second terminal of the switch component and the switch control circuit, and configured to divide the output voltage to output a divided voltage;
wherein the switch control circuit is configured to set a current value of the control current according to the control voltage and the divided voltage.

11. The inrush current suppression circuit according to claim 10, wherein the voltage dividing circuit includes:
a first voltage dividing resistor, wherein a first terminal of the first voltage dividing resistor is connected to the second terminal of the switch component; and
a second voltage dividing resistor, wherein a first terminal of the second voltage dividing resistor is connected to a second terminal of the first voltage dividing resistor, and a voltage dividing node between the first terminal of the second voltage dividing resistor and the second terminal of the first voltage dividing resistor is connected to the switch control circuit.

12. The inrush current suppression circuit according to claim 9, further comprising:
a ramp voltage generating circuit connected to the switch control circuit, and configured to output the ramp voltage to the switch control circuit.

13. The inrush current suppression circuit according to claim 12, wherein the ramp voltage generating circuit includes:
a ramp capacitor, wherein a first terminal of the ramp capacitor is connected to the switch control circuit, and a second terminal of the ramp capacitor is grounded; and
a ramp current source connected to the first terminal of the ramp capacitor and configured to output a ramp current to the ramp capacitor;
wherein the switch control circuit is configured to receive a voltage of the first terminal of the ramp capacitor as the ramp voltage.

14. The inrush current suppression circuit according to claim 9, further comprising:
an output capacitor, wherein a first terminal of the output capacitor is connected to the second terminal of the switch component, and a second terminal of the output capacitor is grounded.

15. The inrush current suppression circuit according to claim 9, wherein the compensation circuit includes:
a compensation transistor, wherein a control terminal of the compensation transistor is connected to the control node, and a second terminal of the compensation transistor is connected to the second terminal of the switch component;
a bias current source connected to a first terminal of the compensation transistor, and configured to output a bias current to the first terminal of the compensation transistor;
a compensation control circuit connected to the first terminal of the compensation transistor, and configured to output a compensation control voltage according to a voltage of the first terminal of the compensation transistor; and
a compensation current source configured to output the compensation current; and
a compensation switch, wherein a first terminal of the compensation switch is connected to the compensation current source, a second terminal of the compensation switch is connected to the control node, and a control terminal of the switch component is connected to the switch control circuit.

16. The inrush current suppression circuit according to claim 15, wherein the switch control circuit includes:
an inverter, wherein an input terminal of the inverter is connected to the first terminal of the compensation transistor; and
a flip-flop, wherein a first input terminal of the flip-flop is connected to an output terminal of the inverter, a second input terminal of the flip-flop is coupled to an enable logic level, and an inverting output terminal of the flip-flop is connected to the control terminal of the compensation switch.
